(19) United States
(12) Patent Application Publication
(10) Pub. No.: US 2018/0218687 A1
(43) Pub. Date: Aug. 2, 2018

(54) VOLTAGE CONVERTING CIRCUIT, VOLTAGE CONVERTING MTHOD, GATE DRIVING CIRCUIT, DISPLAY PANEL AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventors: Guohuo SU, Beijing (CN); Zhihua SUN, Beijing (CN); Jianming WANG, Beijing (CN); Zhihao ZHANG, Beijing (CN); XU ZHANG, Beijing (CN); Yinlong ZHANG, Beijing (CN)

(21) Appl. No.: 15/518,362

(22) PCT Filed: Jul. 29, 2016
(86) PCT No.: PCT/CN2016/092202

§ 371 Date: Apr. 11, 2017

(30) Foreign Application Priority Data
Jan. 4, 2016 (CN) 201610005886.8

(51) Int. Cl. G09G 3/3266; G09G 3/36; H03K 3/356

(52) U.S. Cl. CPC G09G 3/3266; G09G 2310/0289; H03K 3/356104; G09G 3/3677

(57) ABSTRACT

A voltage converting circuit, a voltage converting method, a gate driving circuit, a display panel and a display device are provided. The voltage converting circuit includes: a control sub-circuit and an output sub-circuit. The control sub-circuit is configured to output first conversion control signal to the output sub-circuit when input terminal of the control sub-circuit receives first voltage signal, and output second conversion control signal to the output sub-circuit when the input terminal of the control sub-circuit receives second voltage signal; and the output sub-circuit is configured to output third voltage signal when receiving the first conversion control signal from the control sub-circuit, and output fourth voltage signal when receiving the second conversion control signal from the control sub-circuit. Thus, the voltage conversion circuit can not only convert the first voltage signal into the third voltage signal but also convert the second voltage signal into the fourth voltage signal.

### TECHNICAL FIELD

The present disclosure relates to a field of display technique, in particular to a voltage converting circuit, a voltage converting method, a gate driving circuit, a display panel and a display device.

### BACKGROUND

As display technique develops constantly, panel displays such as a light emitting diode (LED), an organic light emitting diode (OLED), a plasma display panel (PDP) and a liquid crystal display (LCD) or the like grow fast.

In the panel displays, a gate driving circuit applies gate scanning signals to respective gate lines in a display panel, and a data driving circuit applies data signals to respective data lines in the display panel. In the gate driving circuit, a voltage converting circuit converts an input voltage signal having a small amplitude value into a voltage signal having a large amplitude value which is capable of driving pixel points. In general circumstances, the voltage signal input by the voltage converting circuit is an operating voltage VDD (generally 3.3V) and an operating ground GND (0V), and voltage signals output after being converted is a high voltage signal VGH (approximately 30V) and a low voltage signal VGL (approximately −8V).

In the existing voltage converting circuit, at least two stages of converting circuits are needed to realize conversion of voltages. As shown in FIG. 1, two stages of converting circuits are adopted to realize voltage conversion. A first stage of converting circuit only increases VDD to VGH, and a second stage of converting circuit only reduces GND to VGL. As a result, there are many circuit devices, and the circuit structure is relatively complicated.

### SUMMARY

Given that, there are provided in embodiments of the present disclosure a voltage converting circuit, a voltage converting method, a gate driving circuit, a display panel and a display device, wherein a structure of the voltage converting circuit is optimized.

Therefore, there is provided in an embodiment of the present disclosure a voltage converting circuit, comprising: a control sub-circuit and an output sub-circuit, wherein an input terminal of the control sub-circuit is connected to a signal input terminal of the voltage converting circuit, an output terminal of the output sub-circuit is connected to a signal output terminal of the voltage converting circuit, and the control sub-circuit is configured to output a first conversion control signal to the output sub-circuit when the input terminal of the control sub-circuit receives a first voltage signal and output a second conversion control signal to the output sub-circuit when the input terminal of the control sub-circuit receives a second voltage signal; and the output sub-circuit is configured to output a third voltage signal when the first conversion control signal is received from the control sub-circuit and output a fourth voltage signal when the second conversion control signal is received from the control sub-circuit.

According to the embodiment of the present disclosure, the control sub-circuit comprises: a first control sub-circuit and a second control sub-circuit, wherein the first control sub-circuit is configured to output a first control signal to the second control sub-circuit when an input terminal of the first control sub-circuit receives the first voltage signal, and output a second control signal to the second control sub-circuit when an input terminal of the first control sub-circuit receives the second voltage signal; and the second control sub-circuit is configured to output the first conversion control signal to the output sub-circuit when an input terminal of the second control sub-circuit receives the first control signal, and output the second conversion control signal to the output sub-circuit when an input terminal of the second control sub-circuit receives the second control signal

According to the embodiment of the present disclosure, an output terminal of the first control sub-circuit is connected to a control terminal of the second control sub-circuit; a first input terminal of the second control sub-circuit is connected to a first reference voltage terminal for inputting a first reference voltage signal, a second input terminal thereof is connected to a second reference voltage terminal for inputting a second reference voltage signal, a first output terminal thereof is connected to the first control terminal of the output sub-circuit, a second output terminal thereof is connected to a third reference voltage terminal for inputting a third voltage signal and a first input terminal of the output sub-circuit respectively, a third output terminal thereof is connected to a second control terminal of the output sub-circuit, and a fourth output terminal thereof is connected to a fourth reference voltage terminal for inputting a fourth voltage signal and a second input terminal of the output sub-circuit respectively.

According to an embodiment of the present disclosure, the first control sub-circuit comprises an inverter; and an input terminal of the inverter is connected to the signal input terminal, and an output terminal thereof is connected to the control terminal of the second control sub-circuit.

According to an embodiment of the present disclosure, the second control sub-circuit comprises: a first switch transistor, a second switch transistor, a first resistor and a second resistor; wherein a gate of the first switch transistor and a gate of the second switch transistor are connected to the output terminal of the inverter, a source of the first switch transistor is connected to the first reference voltage terminal for inputting the first reference voltage signal, and a drain of the first switch transistor is connected to a first terminal of the first resistor and the first control terminal of the output sub-circuit respectively; a second terminal of the first resistor is connected to the third reference voltage terminal for inputting the third voltage signal and the first input terminal of the output sub-circuit respectively; a source of the second switch transistor is connected to the second reference voltage terminal for inputting the second reference voltage signal, and a drain thereof is connected to a first terminal of the second resistor and the second control terminal of the output sub-circuit respectively; and a second terminal of the second resistor is connected to the fourth reference voltage terminal for inputting the fourth voltage signal and the second input terminal of the output sub-circuit respectively.

According to an embodiment of the present disclosure, the output sub-circuit comprises: a third switch transistor and a fourth switch transistor; wherein a gate of the third switch transistor is connected to the drain of the first switch transistor, a source thereof is connected to the third reference voltage terminal for inputting the third voltage signal, and the gate and source thereof are connected to the first terminal and the second terminal of the first resistor respectively, and a drain thereof and a drain of the fourth switch transistor are connected to the signal output terminal; and a gate of the fourth switch transistor is connected to the drain of the second switch transistor, a source thereof is connected to the fourth reference voltage terminal for inputting the fourth voltage signal, and the gate and source thereof are connected to the first terminal and the second terminal of the second resistor respectively.

According to the embodiment of the present disclosure, a first input terminal of the control sub-circuit is connected to the first reference voltage terminal for inputting the first reference voltage signal, a second input terminal thereof is connected to the second reference voltage terminal for inputting the second reference voltage signal, a first output terminal thereof is connected to the first control terminal of the output sub-circuit, a second output terminal is connected to the third reference voltage terminal for inputting the third voltage signal and the first input terminal of the output sub-circuit respectively, a third output terminal thereof is connected to the second control terminal of the output sub-circuit, and a fourth output terminal thereof is connected to the fourth reference voltage terminal for inputting the fourth voltage signal and the second input terminal of the output sub-circuit respectively.

According to the embodiment of the present disclosure, the control sub-circuit comprises: a first switch transistor, a second switch transistor, a first resistor and a second resistor; wherein a gate of the first switch transistor and a gate of the second switch transistor are connected to the input terminal of the control sub-circuit, a source of the first switch transistor is connected to the first reference voltage terminal for inputting the first reference voltage signal, and a drain thereof is connected to a first terminal of the first resistor and the first control terminal of the output sub-circuit respectively; a second terminal of the first resistor is connected to the third reference voltage terminal for inputting the third voltage signal and the first input terminal of the output sub-circuit respectively; a source of the second switch transistor is connected to the second reference voltage terminal for inputting the second reference voltage signal, a drain thereof is connected to a first terminal of the second resistor and the second control terminal of the output sub-circuit respectively; and a second terminal of the second resistor is connected to the fourth reference voltage terminal for inputting the fourth voltage signal and the second input terminal of the output sub-circuit respectively.

According to the embodiment of the present disclosure, the output sub-circuit comprises: a third switch transistor and a fourth switch transistor; wherein a gate of the third switch transistor is connected to the drain of the second switch transistor, a source thereof is connected to the third reference voltage terminal for inputting the third voltage signal, and the gate and the source thereof are connected to the first terminal and the second terminal of the second resistor respectively, and a drain of the third switch transistor and a drain of the fourth switch transistor are connected to the signal output terminal; and a gate of the fourth switch transistor is connected to the drain of the first switch transistor, a source thereof is connected to the fourth reference voltage terminal for inputting the fourth voltage signal, and the gate and the source thereof are connected to the first terminal and the second terminal of the first resistor respectively.

According to the embodiment of the present disclosure, a voltage value of the third voltage signal is greater than a voltage value of the first voltage signal; a voltage value of the first voltage signal is greater than a voltage value of the second voltage signal; and a voltage value of the second voltage signal is greater than a voltage value of the fourth voltage signal.

According to the embodiment of the present disclosure, in the voltage converting circuit provided in the embodiment of the present disclosure, a voltage value of the first reference voltage signal is smaller than or equal to a voltage value of the first voltage signal; a voltage value of the second reference signal is greater than or equal to a voltage value of the second voltage signal, and smaller than the voltage value of the first reference voltage signal.

In a possible implementation, in the voltage converting circuit provided in the embodiment of the present disclosure, the first switch transistor and the third switch transistor are P type transistors; the second switch transistor and the fourth switch transistor are N type transistors.

There is further provided in an embodiment of the present disclosure a voltage converting method, comprising: outputting a first conversion control signal to an output sub-circuit by a control sub-circuit and outputting a third voltage signal under control of the first conversion control signal by the output sub-circuit when a signal input terminal of a voltage conversion circuit is input a first voltage signal; and outputting a second conversion control signal to the output sub-circuit by the control sub-circuit and outputting a fourth voltage signal under control of the second conversion control signal by the output sub-circuit when the signal input terminal of the voltage conversion circuit receives a second voltage signal.

In a possible implementation, in the voltage converting method provided in the embodiment of the present disclosure, a voltage value of the third voltage signal is greater than a voltage value of the first voltage signal; a voltage value of the first voltage signal is greater than a voltage value of the second voltage signal; a voltage value of the second voltage signal is greater than a voltage value of the fourth voltage signal.

There is further provided in an embodiment of the present disclosure a gate driving circuit, comprising: the voltage converting circuit provided in the embodiment of the present disclosure.

There is further provided in an embodiment of the present disclosure a display panel, comprising: the gate driving circuit provided in the embodiment of the present disclosure.

There is further provided in an embodiment of the present disclosure a display device, comprising: the display panel provided in the embodiment of the present disclosure.

There are provided in the embodiments of the present disclosure the voltage converting circuit, its voltage converting method and relevant apparatus. In the voltage converting circuit, the first control sub-circuit outputs the first control signal to the second control sub-circuit when being input the first voltage signal, the second control sub-circuit outputs the third control signal (first conversion control signal) to the output sub-circuit under control of the first control signal, and the output sub-circuit outputs the first voltage signal under control of the third control signal; the first control sub-circuit outputs the second control signal to the second control sub-circuit when being input the second voltage signal, the second control sub-circuit outputs the fourth control signal (second conversion control signal) to the output sub-circuit under control of the second control signal, and the output sub-circuit outputs the fourth voltage signal under control of the fourth control signal. In this way, the voltage conversion circuit can not only convert the first voltage signal into the third voltage signal but also convert the second voltage signal into the fourth voltage signal. Both rise and reduction of voltages are realized through this voltage converting circuit. Conversion of voltages could be realized by using only one stage of circuit, and thus the structure of this voltage converting circuit is simple.

### BRIEF DESCRIPTION OF THE DRAWINGS

FIG. 1 is a schematic diagram of structure of an existing voltage converting circuit;

FIG. 2 is one schematic diagram of structure of a voltage converting circuit provided in an embodiment of the present disclosure;

FIG. 3 is another schematic diagram of structure of a voltage converting circuit provided in an embodiment of the present disclosure;

FIG. 4 is a timing diagram of an input signal and an output signal of a voltage converting circuit provided in an embodiment of the present disclosure;

FIG. 5 is another schematic diagram of structure of a voltage converting circuit provided in an embodiment of the present disclosure;

FIG. 6 is one flow diagram of a voltage converting method provided in an embodiment of the present disclosure; and

FIG. 7 is another flow diagram of a voltage converting method provided in an embodiment of the present disclosure.

### DETAILED DESCRIPTION

Specific implementations of a voltage converting circuit, a voltage converting method and relevant apparatus provided in embodiments of the present disclosure will be described below in detail by combing with accompanying figures. Obviously, the embodiments described below are just a part of embodiments of the present disclosure, but not all the embodiments. Based on the embodiments in the present disclosure, all the other embodiments obtained by those ordinary skilled in the art without paying any inventive labor fall into the scope sought for protection in the present disclosure.

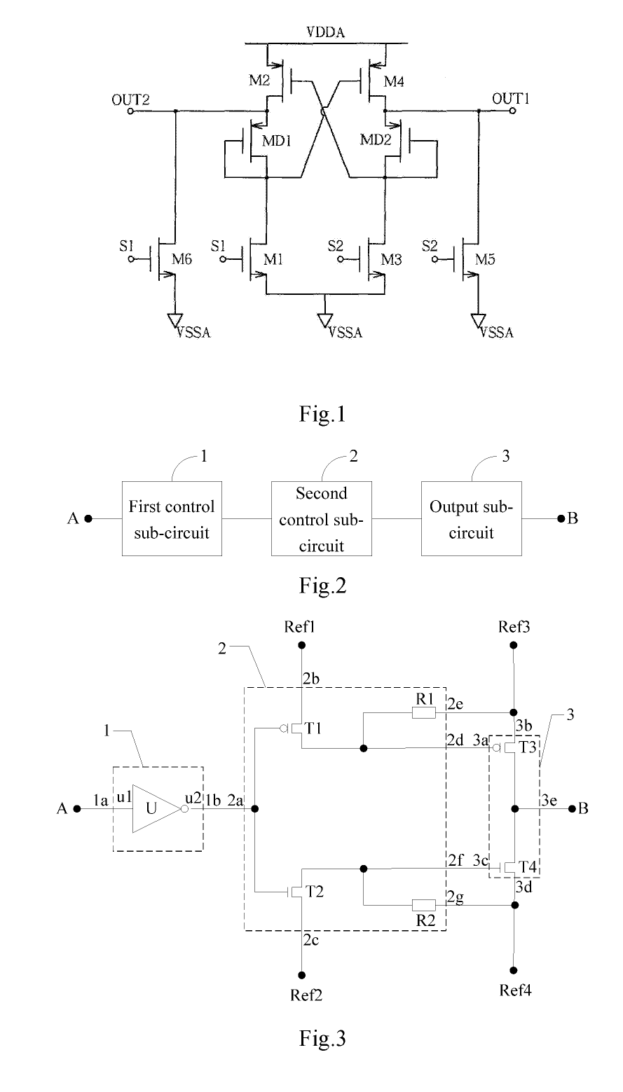

A voltage converting circuit provided in an embodiment of the present disclosure, as shown in FIG. 2, comprises: a first control sub-circuit 1, a second control sub-circuit 2 and an output sub-circuit 3.

An input terminal A of the first control sub-circuit 1 is taken as a signal input terminal A of the voltage converting circuit, and an output terminal of the output sub-circuit 3 is taken as a signal output terminal B of the voltage converting circuit.

When the input terminal of the first control sub-circuit 1 receives a first voltage signal, an output terminal of the first control sub-circuit 1 outputs a first control signal to the second control sub-circuit 2; and when the input terminal of the first control sub-circuit 1 receives a second voltage signal, the output terminal of the first control sub-circuit 1 outputs a second control signal to the second control sub-circuit 2.

When the second control sub-circuit 2 receives the first control signal from the first control sub-circuit 1, an output terminal of the second control sub-circuit 2 outputs a third control signal to the output sub-circuit 3; and when the second control sub-circuit 2 receives the second control signal from the first control sub-circuit 1, the output terminal of the second control sub-circuit 2 outputs a fourth control signal to the output sub-circuit 3.

When the output sub-circuit 3 receives the third control signal from the second control sub-circuit 2, an output terminal of the output sub-circuit 3 outputs a third voltage signal; and when the output sub-circuit 3 receives the fourth control signal from the second control sub-circuit 2, the output terminal of the output sub-circuit 3 outputs a fourth voltage signal.

In the voltage converting circuit provided in the embodiment of the present disclosure, the first control sub-circuit outputs the first control signal to the second control sub-circuit when being input the first voltage signal, the second control sub-circuit outputs the third control signal to the output sub-circuit under control of the first control signal, and the output sub-circuit outputs the third voltage signal under control of the third control signal; the first control sub-circuit outputs the second control signal to the second control sub-circuit when being input the second voltage signal, the second control sub-circuit outputs the fourth control signal to the output sub-circuit under control of the second control signal, and the output sub-circuit outputs the fourth voltage signal under control of the fourth control signal. In this way, the voltage conversion circuit is capable of converting the first input signal into the first voltage signal and also converting the second input signal into the second voltage signal. Both rise and reduction of voltages are realized through this voltage converting circuit. Conversion of voltages could be realized by using only one stage of circuit, and thus the structure of this voltage converting circuit is simple.

As an example, by utilizing the voltage converting circuit provided in the embodiment of the present disclosure, a voltage value of the first voltage signal can be increased to a voltage value of the third voltage signal, and a voltage value of the second voltage signal can be reduced to a voltage value of the fourth voltage signal. That is to say, in the embodiment of the present disclosure, the voltage value of the third voltage signal is greater than the voltage value of the first voltage signal, the voltage value of the first voltage signal is greater than the voltage value of the second voltage signal, and the voltage value of the second voltage signal is greater than the voltage value of the fourth voltage signal.

Alternatively, as another example, by utilizing the voltage converting circuit provided in the embodiment of the present disclosure, the voltage value of the first voltage signal can be reduced to the voltage value of the third voltage signal, the voltage value of the second voltage signal can be increased to the voltage value of the fourth voltage value. That is, in the embodiment of the present disclosure, the voltage value of the third voltage signal is smaller than the voltage value of the first voltage signal, the voltage value of the first voltage signal is smaller than the voltage value of the second voltage signal, and the voltage value of the second voltage signal is smaller than the voltage value of the fourth voltage signal.

The embodiment given below in the present disclosure is described by taking the voltage value of the first voltage signal being increased to the voltage value of the third voltage signal and the voltage value of the second voltage signal being reduced to the voltage value of the fourth voltage signal as an example, that is, the voltage value of the third voltage signal is greater than the voltage value of the first voltage signal, the voltage value of the first voltage signal is greater than the voltage value of the second voltage signal, and the voltage value of the second voltage signal is greater than the voltage value of the fourth voltage signal. In particular, the first voltage signal can be a VDD signal, and its voltage value is generally 3.3V; the second voltage signal can be a GND signal, and its voltage value is 0V; the third voltage signal can be a VGH signal, and its voltage value is 30V; the fourth voltage signal is a VGL signal, and its voltage value is −8V.

Of course, in the voltage converting circuit provided in the embodiment of the present disclosure, voltage values of the first voltage signal, the second voltage signal, the third voltage signal and the fourth voltage signal can also be other values, to which no limitation is given herein.

According to the embodiments of the present disclosure, in the voltage converting circuit provided in the embodiment of the present disclosure, as shown in FIG. 3, an input terminal 1a of the first control sub-circuit 1 is connected to the signal input terminal A of the voltage converting circuit, and an output terminal 1b of the first control sub-circuit 1 is connected to a control terminal 2a of the second control sub-circuit 2.

A first input terminal 2b of the second control sub-circuit 2 is connected to a first reference voltage terminal Ref1 for inputting a first reference signal, a second input terminal 2c thereof is connected to a second reference voltage terminal Ref2 for inputting a second reference voltage signal, a first output terminal 2d thereof is connected to a first control terminal 3a of the output sub-circuit 3, a second output terminal 2e thereof is connected to a third reference voltage terminal Ref3 for inputting a third voltage signal and a first input terminal 3b of the output sub-circuit 3 respectively, and a third output terminal 2f thereof is connected a second control terminal 3c of the output sub-circuit 3, and a fourth output terminal 2g thereof is connected to a fourth reference voltage terminal Ref4 for inputting a fourth voltage signal and a second input terminal 3d of the output sub-circuit 3.

An output terminal 3e of the output sub-circuit 3 is connected to a signal output terminal B of the voltage converting circuit.

In specific implementation, in the voltage converting circuit provided in the embodiment of the present disclosure, the voltage value of the first reference voltage signal may be smaller than, equal to or greater than the voltage value of the first voltage signal, to which no limitation is made herein; the voltage value of the second reference voltage signal may be smaller than, equal to or greater than the voltage value of the second voltage signal, to which no limitation is made herein; just as it is ensured that the voltage value of the second reference voltage signal is smaller than the voltage value of the first reference voltage signal, such that the output sub-circuit 3 is capable of operating normally. In the following description, description is given by taking the voltage value of the first reference voltage signal being equal to the voltage value of the first voltage signal and the voltage value of the second reference voltage signal being equal to the voltage value of the second voltage signal as an example. For example, both the first reference voltage signal and the first voltage signal are VDD signals, and their voltage values are generally 3.3V; and both the second reference voltage signal and the second voltage signal are GND signals, and their voltage values are 0V.

As an example, in the voltage converting circuit provided in the embodiment of the present disclosure, as shown in FIG. 3, the first control sub-circuit 1 can specifically comprise: an inverter U; an input terminal u1 of the inverter U (i.e., input terminal 1a of the first control sub-circuit) is connected to the signal input terminal A, an output terminal u2 thereof (i.e., output terminal 1b of the first control sub-circuit) is connected to the control terminal 2a of the second control sub-circuit 2.

In the voltage converting circuit provided in the embodiment of the present disclosure, when the first control sub-circuit 1 adopts particularly the above inverter U as a specific structure, its operation principle is as follows: when the inverter U receives a signal VDD transmitted by the signal input terminal A, the inverter U outputs a GND signal to the control terminal 2a of the second control sub-circuit 2; and when the inverter U receives the GND signal transmitted by the signal input terminal A, the inverter U outputs the VDD signal to the control terminal 2a of the second control sub-circuit 2.

As an example, in the voltage converting circuit provided in the embodiment of the present disclosure, as shown in FIG. 3, the second control sub-circuit 2 can particularly comprise: a first switch transistor T1, a second switch transistor T2, a first resistor R1 and a second resistor R2; wherein a gate of the first switch transistor T1 and a gate of the second switch transistor T2 are connected to the output terminal u2 of the inverter U, a source of the first switch transistor T1 is connected to the first reference voltage terminal Ref1 for inputting the first reference voltage signal, a drain thereof is connected to a first terminal of the first resistor R1 and the first control terminal 3a of the output sub-circuit 3 respectively; a second terminal of the second resistor R1 is connected to the third reference voltage terminal Ref3 for inputting the third voltage signal and the first input terminal 3b of the output sub-circuit 3 respectively; a source of the second switch transistor T2 is connected to the second reference voltage terminal Ref2 for inputting the second reference voltage signal, a drain thereof is connected to a first terminal of the second resistor R2 and the second control terminal 3c of the output sub-circuit 3 respectively; and a second terminal of the second resistor R2 is connected to the fourth reference voltage terminal Ref4 for inputting the fourth voltage signal and the second input terminal 3d of the output sub-circuit 3 respectively.

In specific implementation, in the voltage converting circuit provided in the embodiment of the present disclosure, when both the first voltage signal and the first reference voltage signal are VDD signals and both the second voltage signal and the second reference voltage signal are GND signals, the first switch transistor is a P type transistor, and the second switch transistor is an N type transistor.

In the voltage converting circuit provided in the embodiment of the present disclosure, when the second control sub-circuit 2 adopts particularly the first switch transistor T1 of P type, the second switch transistor T2 of N type, the first resistor R1 and the second resistor R2 as a specific structure, its operation principle is as follows: when the gate of the first switch transistor T1 and the gate of the second switch transistor T2 receive the GND signal transmitted by the inverter U, since a voltage value (0V) of the GND signal input to the gate of the first switch transistor T1 is smaller than a voltage value (3.3) of the VDD signal input to the source of the first switch transistor T1 and the first switch transistor T1 is the P type transistor, the first switch transistor T1 is in a turn-on state, such that the first reference voltage terminal Ref1 for inputting the first reference voltage signal outputs the VDD signal to the first control terminal 3a of the output sub-circuit 3 through the first switch transistor T1, on the other hand, since the voltage value (0V) of the GND signal input to the gate of the second switch transistor T2 is equal to the voltage value (0V) of the GND signal input to the source of the second switch transistor T2 and the second switch transistor T2 is the N type transistor, the second switch transistor T2 is turned off, and the fourth reference voltage terminal Ref4 for inputting the fourth voltage signal outputs the VGL signal to the second control terminal 3c of the output module 3 through the second resistor R2; when the gate of the first switch transistor T1 and the gate of the second switch transistor T2 receive the VDD signal transmitted by the inverter U, since the voltage value (3.3V) of the VDD signal input to the gate of the first switch transistor T1 is equal to the voltage value (3.3V) of the VDD signal input to the source of the first switch transistor T1 and the first switch transistor T1 is the P type transistor, the first switch transistor T1 is turned off, and the third reference voltage terminal Ref3 for inputting the third voltage signal outputs the VGH signal to the first control terminal 3a of the output module 3. On the other hand, since the voltage value (3.3V) of the VDD signal input to the gate of the second switch transistor T2 is greater than the voltage value (0V) of the GND signal input to the source of the second switch transistor T2 and the second switch transistor T2 is the N type transistor, the second switch transistor T2 is in a turn-on state, such that the second reference voltage terminal Ref2 for inputting the second reference voltage outputs the GND signal to the second control terminal 3c of the output sub-circuit 3 through the second switch transistor T2.

In specific implementation, in the voltage converting circuit provided in the embodiment of the present disclosure, as shown in FIG. 3, the output sub-circuit 3 can particularly comprise: a third switch transistor T3 and a fourth switch transistor T4; wherein a gate of the third switch transistor T3 is connected to the drain of the first switch transistor T1, a source thereof is connected to the third reference voltage terminal Ref3 for inputting the third voltage signal, the gate and the source thereof is connected to the first terminal and the second terminal of the first resistor R1 respectively, and a drain thereof is connected to the signal output terminal B and a drain of the fourth switch transistor T4 respectively; a gate of the fourth switch transistor T4 is connected to the drain of the second switch transistor T2, a source thereof is connected to the fourth reference voltage terminal Ref4 for inputting the fourth voltage signal, and the gate and the source thereof are connected to the first terminal and the second terminal of the second resistor R2 respectively.

In specific implementation, in the voltage converting circuit provided in the embodiment of the present disclosure, when both the first voltage signal and the first reference voltage signal are VDD signals, both the second voltage signal and the second reference voltage signal are GND signals, the first switch transistor is the P type transistor, the second switch transistor is the N type transistor, the third voltage signal is the VGH signal, and the fourth voltage signal is the VGL signal, the third switch transistor is the P type transistor, and the fourth switch transistor is the N type transistor.

In the voltage converting circuit provided in the embodiment of the present disclosure, when the output sub-circuit 3 adopts specifically the third switch transistor T3 of P type and the fourth switch transistor T4 of N type as a specific structure, its operation principle is as follows: when the gate of the third switch transistor T3 receives the VDD signal transmitted by the first reference voltage terminal Ref1 for inputting the first reference voltage signal, and when the gate of the fourth switch transistor T4 receives the VGL signal transmitted by the fourth reference voltage terminal Ref4 for inputting the fourth voltage signal, since the voltage value (3.3V) of the VDD signal input to the gate of the third switch transistor T3 is smaller than the voltage value (30V) of the VGH signal input to the source of the third switch transistor T3, and the third switch transistor T3 is the P type transistor, the third switch transistor T3 is in the turn-on state, such that the third reference voltage terminal Ref3 for inputting the third voltage signal outputs the VGH signal to the signal output terminal B through the third switch transistor T3. On the other hand, since a voltage value (−8V) of the VGL signal input to the gate of the fourth switch transistor T4 is equal to a voltage value (−8V) of the VGL signal input to the source of the fourth switch transistor T4, and the fourth switch transistor T4 is the N type transistor, the fourth switch transistor T4 is turned off; when the gate of the third switch transistor T13 receives the VGH signal transmitted by the third reference voltage terminal Ref3 for inputting the third voltage signal, and when the gate of the fourth switch transistor T14 receives the GND signal transmitted by the second reference voltage terminal Ref2 for inputting the second reference voltage signal, since a voltage value (30V) of the VGH signal input to the gate of the third switch transistor T3 is equal to a voltage value (30V) of the VGH signal input to the source of the third switch transistor T3, and the third switch transistor T3 is the P type transistor, the third switch transistor T3 is turned off. On the other hand, since the voltage value (0V) of the GND signal input to the gate of the fourth switch transistor T4 is greater than the voltage value (−8V) of the VGL signal input to the source of the fourth switch transistor T4, and the fourth switch transistor T4 is the N type transistor, the fourth switch transistor T4 is in the turn-on state, such that the fourth reference voltage signal for inputting the fourth voltage signal outputs the VGL signal to the signal output terminal B through the fourth switch transistor t4.

It needs to specify that switch transistors mentioned in the embodiment of the present disclosure can be thin film transistors (TFT), and metal oxide semiconductor (MOS) transistors, to which no limitation is given. In specific implementation, sources and drains of these transistors can be exchanged with each other, and no specific distinction is made. Specific embodiments are described by taking the switch transistors being thin film transistors as an example.

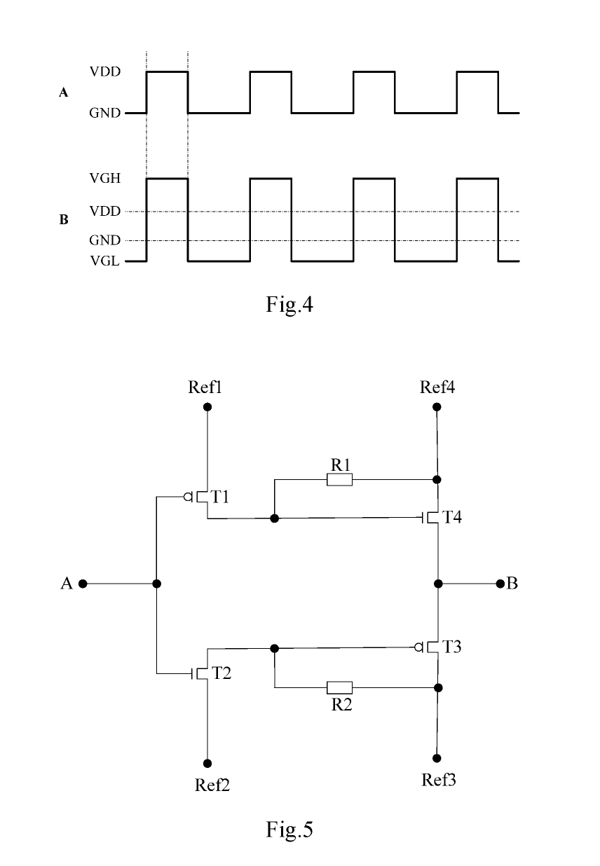

Operation principle of the voltage converting circuit will be described in detail by specific examples as shown in FIG. 3. FIG. 4 is a timing diagram of the input signal of the signal input terminal A of the voltage converting circuit as shown in FIG. 3 and the output signal of the signal output terminal B thereof.

In a first period of time, the inverter U receives the VDD signal transmitted by the signal input terminal A, and the inverter U outputs the GND signal to the control terminal 2a of the second control sub-circuit; when the gate of the first switch transistor T1 and the gate of the second switch transistor T2 in the second control sub-circuit receive the GND signal transmitted by the inverter U, the first switch transistor T1 is in a turn-on state, the second switch transistor T2 is turned off, the first reference voltage terminal Ref1 for inputting the first reference voltage signal outputs the VDD signal to the first control terminal 3a of the output sub-circuit 3 through the first switch transistor T1, and the fourth reference voltage terminal Ref4 for inputting the fourth voltage signal outputs the VGL signal to the second control terminal 3c of the output sub-circuit 3 through the second resistor R2; when the gate of the third switch transistor T3 receives the VDD signal transmitted by the first reference voltage terminal Ref1 for inputting the first reference voltage signal, and when the gate of the fourth switch transistor T4 receives the VGL signal transmitted by the fourth reference voltage terminal Ref4 for inputting the fourth voltage signal, the third switch transistor T3 is in the turn-on state, the fourth switch transistor T4 is turned off, the third reference voltage terminal Ref3 for inputting the third voltage signal outputs the VGH signal to the signal output terminal B through the third switch transistor T3.

In a second period of time, the inverter U receives the GND signal transmitted by the signal input terminal A. and the inverter U outputs the VDD signal to the control terminal 2a of the second control sub-circuit; when the gate of the first switch transistor T1 and the gate of the second switch transistor T2 in the second control sub-circuit receive the VDD signal transmitted by the inverter U, the first switch transistor T1 is turned off, the second switch transistor T2 is in the turn-on state, the third reference voltage terminal Ref3 for inputting the third voltage signal outputs the VGH signal to the first control terminal 3a of the output sub-circuit 3 through the first resistor R1, the second reference voltage terminal Ref2 for inputting the second reference voltage signal outputs the GND signal to the second control terminal 3c of the output sub-circuit 3 through the second switch transistor T2; when the gate of the third switch transistor T3 receives the VGH signal transmitted by the third reference voltage terminal Ref3 for inputting the third voltage signal, and when the gate of the fourth switch transistor T4 receives the GND signal transmitted by the second reference voltage Ref2 for inputting the second reference voltage signal, the third switch transistor T3 is turned off, the fourth switch transistor T4 is in the turn-on state, and the fourth reference voltage terminal Ref4 for inputting the fourth voltage signal outputs the VGL signal to the signal output terminal B through the fourth switch transistor T4.

It needs to specify that the voltage converting circuit provided in the embodiment of the present disclosure is not limited to the circuit structure as shown in FIG. 3. Also, the inverter U 1 can be removed, and positions of the third switch transistor T3 in the output sub-circuit 3 and the third reference voltage terminal Ref3 for inputting the third voltage signal can be exchanged with positions of the fourth switch transistor T4 and the fourth reference voltage terminal Ref4 for inputting the fourth voltage signal, i.e., the circuit structure as shown in FIG. 5. Such structure is also capable of realizing that when the signal input terminal A is input the first voltage signal (VDD signal), the signal output terminal B outputs the third voltage signal (VGH signal); when the signal input terminal A is input the second voltage signal (GND signal), the signal output terminal B outputs the fourth voltage signal (VGL signal). Operation principle of the voltage converting circuit as shown in FIG. 5 is similar to the operation principle of the voltage converting circuit as shown in FIG. 3, and thus no further details is given herein.

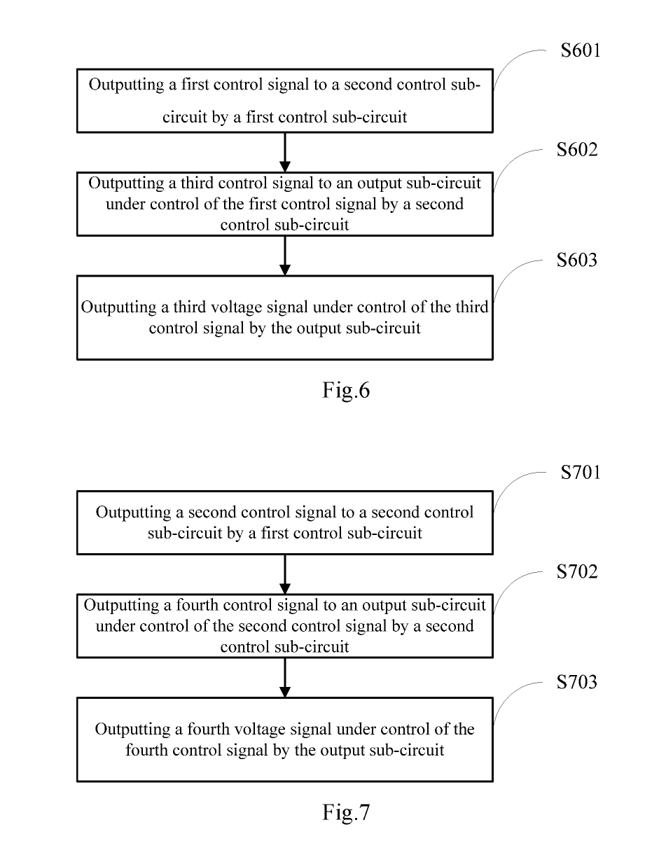

Based on a same inventive concept, there is further provided in an embodiment of the present disclosure a voltage converting method. When a signal input terminal is input a first voltage signal, i.e., in the first period of time, as shown in FIG. 6, following operations are performed.

In step S601, the first control sub-circuit outputs the first control signal to the second control sub-circuit.

In step S602, the second control sub-circuit outputs the third control signal to the output sub-circuit under control of the first control signal.

In step S603, the output sub-circuit outputs the third voltage signal under control of the third control signal.

When the signal input terminal is input the second voltage signal, as shown in FIG. 7, following operations are performed.

In step S701, the first control sub-circuit outputs the second control signal to the second control sub-circuit.

In step S702, the second control sub-circuit outputs the fourth control signal to the output sub-circuit under control of the second control signal.

In step S703, the output sub-circuit outputs the fourth voltage signal under control of the fourth control signal.

In specific implementation, the voltage converting method provided in the embodiment of the present disclosure can be utilized to increase the voltage value of the first voltage signal to the voltage value of the third voltage signal and reduce the voltage value of the second voltage signal to the voltage value of the fourth voltage signal. That is to say, the voltage value of the third voltage signal is greater than the voltage value of the first voltage signal, and the voltage value of the first voltage signal is greater than the voltage value of the second voltage signal, and the voltage value of the second voltage signal is greater than the voltage value of the fourth voltage signal. In particular, the first voltage signal can be a VDD signal, and its voltage value is generally 3.3V; the second voltage signal can be a GND signal, and its voltage value is 0V; the third voltage signal can be a VGH signal, and its voltage value is approximately 30V; the fourth voltage signal can be a VGL signal, and its voltage value is approximately −8V. Then, in the voltage converting method provided in the embodiment of the present disclosure, the first control sub-circuit outputs the first control signal to the second control sub-circuit when receiving the VDD signal of the signal input terminal; the second control sub-circuit outputs the third control signal to the output sub-circuit under control of the first control signal; the output sub-circuit outputs the VGH signal under control of the third control signal; the first control sub-circuit outputs the second control signal to the second control sub-circuit when receiving the GND signal of the signal input terminal; the second control sub-circuit outputs the fourth control signal to the output sub-circuit under control of the second control signal; and the output sub-circuit outputs the VGL signal under control of the fourth control signal.

Of course, alternatively, the voltage converting method provided in the embodiment of the present disclosure can also be utilized to reduce the voltage value of the first voltage signal to the voltage value of the third voltage signal and increase the voltage value of second voltage signal to the voltage value of the fourth voltage signal. That is to say, the voltage value of the third voltage signal is smaller than the voltage value of the first voltage signal, the voltage value of the first voltage signal is smaller than the voltage value of the second voltage signal, and the voltage value of the second voltage signal is smaller than the voltage value of the fourth voltage signal, to which no limitation is made.

Based on a same inventive concept, there is further provided in an embodiment of the present disclosure a gate driving circuit, comprising: the voltage converting circuit provided in the embodiment of the present disclosure. Implementation of the gate driving circuit can refer to the embodiment of the voltage converting circuit, and thus no repetitive description is given herein.

Based on a same inventive concept, there is further provided in an embodiment of the present disclosure a display panel, comprising: the gate driving circuit provided in the embodiment of the present disclosure. Implementation of the display panel can refer to the embodiment of the gate driving circuit, and no repetitive description is given herein.

In specific implementation, the display panel provided in the embodiment of the present disclosure can be applicable to flat display panels such as OLED or LCD and the like, to which no limitation is given herein. In particular, the gate driving circuit can be integrated directly on the array substrate in the display panel, or the gate driving circuit can be bonded with the array substrate in the display panel, to which no limitation is given herein.

Based on a same inventive concept, there is further provided in an embodiment of the present disclosure a display device, comprising the display panel provided in the embodiment of the present disclosure. The display device can be any product or means having display function such as a mobile phone, a panel computer, a television, a display, a notebook computer, a digital photo frame, a navigator, a wearable device or the like. Implementation of the display device can refer to the embodiment of the display panel, and thus no repetitive description is given herein.

There are provided in the embodiments of the present disclosure the voltage converting circuit, its voltage converting method and relevant apparatus. In the voltage converting circuit, the first control sub-circuit outputs the first control signal to the second control sub-circuit when being input the first voltage signal, the second control sub-circuit outputs the third control signal (the first conversion control signal) to the output sub-circuit under control of the first control signal, and the output sub-circuit outputs the first voltage signal under control of the third control signal; the first control sub-circuit outputs the second control signal to the second control sub-circuit when being input the second voltage signal, the second control sub-circuit outputs the fourth control signal (the second conversion control signal) to the output sub-circuit under control of the second control signal, and the output sub-circuit outputs the fourth voltage signal under control of the fourth control signal. In this way, the voltage conversion circuit is capable of converting the first voltage signal into the third voltage signal and also converting the second voltage signal into the fourth voltage signal. Both rise and reduction of voltages are realized through this voltage converting circuit. Conversion of voltages could be realized by using only one stage of circuit, and thus the structure of this voltage converting circuit is simple.

Obviously, those skilled in the art can make various alternations and modifications to the present disclosure without departing from the spirit and scope of the present disclosure. As such, if these alternations and modifications of the present disclosure belong to the scope of the claims of the present disclosure as well as their equivalents, then the present disclosure intends to include these alternations and modifications.

The present application claims the priority of a Chinese patent application No. 201610005886.8 filed on Jan. 4, 2016, with an invention title of “LEVEL CONVERTING CIRCUIT, LEVEL CONVERTING METHOD AND RELEVANT APPARATUS”. Herein, the content disclosed by the Chinese patent application is incorporated in full by reference as a part of the present disclosure.

1. A voltage converting circuit, comprising: a control sub-circuit and an output sub-circuit, wherein an input terminal of the control sub-circuit is connected to a signal input terminal of the voltage converting circuit, an output terminal of the output sub-circuit is connected to a signal output terminal of the voltage converting circuit,
the control sub-circuit is configured to output a first conversion control signal to the output sub-circuit when the input terminal of the control sub-circuit receives a first voltage signal, and output a second conversion control signal to the output sub-circuit when the input terminal of the control sub-circuit receives a second voltage signal; and
the output sub-circuit is configured to output a third voltage signal when the first conversion control signal is received from the control sub-circuit and output a fourth voltage signal when the second conversion control signal is received from the control sub-circuit.

2. The voltage converting circuit according to claim 1, wherein the control sub-circuit comprises: a first control sub-circuit and a second control sub-circuit,
the first control sub-circuit is configured to output a first control signal to the second control sub-circuit when an input terminal of the first control sub-circuit receives the first voltage signal, and output a second control signal to the second control sub-circuit when an input terminal of the first control sub-circuit receives the second voltage signal; and
the second control sub-circuit is configured to output the first conversion control signal to the output sub-circuit when an input terminal of the second control sub-circuit receives the first control signal, and output the second conversion control signal to the output sub-circuit when an input terminal of the second control sub-circuit receives the second control signal.

3. The voltage converting circuit according to claim 2, wherein an output terminal of the first control sub-circuit is connected to a control terminal of the second control sub-circuit; and
a first input terminal of the second control sub-circuit is connected to a first reference voltage terminal for inputting a first reference voltage signal, a second input terminal thereof is connected to a second reference voltage terminal for inputting a second reference voltage signal, a first output terminal thereof is connected to the first control terminal of the output sub-circuit, a second output terminal thereof is connected to a third reference voltage terminal for inputting a third voltage signal and a first input terminal of the output sub-circuit respectively, a third output terminal thereof is connected to a second control terminal of the output sub-circuit, and a fourth output terminal thereof is connected to a fourth reference voltage terminal for inputting a fourth voltage signal and a second input terminal of the output sub-circuit respectively.

4. The voltage converting circuit according to claim 3, wherein the first control sub-circuit comprises an inverter; and
an input terminal of the inverter is connected to the signal input terminal, and an output terminal thereof is connected to the control terminal of the second control sub-circuit.

5. The voltage converting circuit according to claim 3, wherein the second control sub-circuit comprises: a first switch transistor, a second switch transistor, a first resistor and a second resistor; wherein
a gate of the first switch transistor and a gate of the second switch transistor are connected to the output terminal of the inverter,
a source of the first switch transistor is connected to the first reference voltage terminal for inputting the first reference voltage signal, and a drain of the first switch transistor is connected to a first terminal of the first resistor and the first control terminal of the output sub-circuit respectively;
a second terminal of the first resistor is connected to the third reference voltage terminal for inputting the third voltage signal and the first input terminal of the output sub-circuit respectively;
a source of the second switch transistor is connected to the second reference voltage terminal for inputting the second reference voltage signal, and a drain thereof is connected to a first terminal of the second resistor and the second control terminal of the output sub-circuit respectively; and
a second terminal of the second resistor is connected to the fourth reference voltage terminal for inputting the fourth voltage signal and the second input terminal of the output sub-circuit respectively.

6. The voltage converting circuit according to claim 3, wherein the output sub-circuit comprises: a third switch transistor and a fourth switch transistor; wherein
a gate of the third switch transistor is connected to the drain of the first switch transistor, a source thereof is connected to the third reference voltage terminal for inputting the third voltage signal, and the gate and source thereof are connected to the first terminal and the second terminal of the first resistor respectively, and a drain thereof and a drain of the fourth switch transistor are connected to the signal output terminal;
a gate of the fourth switch transistor is connected to the drain of the second switch transistor, a source thereof is connected to the fourth reference voltage terminal for inputting the fourth voltage signal, and the gate and source thereof are connected to the first terminal and the second terminal of the second resistor respectively.

7. The voltage converting circuit according to claim 1, wherein a first input terminal of the control sub-circuit is connected to the first reference voltage terminal for inputting the first reference voltage signal, a second input terminal thereof is connected to the second reference voltage terminal for inputting the second reference voltage signal, a first output terminal thereof is connected to the first control terminal of the output sub-circuit, a second output terminal is connected to the third reference voltage terminal for inputting the third voltage signal and the first input terminal of the output sub-circuit respectively, a third output terminal thereof is connected to the second control terminal of the output sub-circuit. and a fourth output terminal thereof is connected to the fourth reference voltage terminal for inputting the fourth voltage signal and the second input terminal of the output sub-circuit respectively.

8. The voltage converting circuit according to claim 7, wherein the control sub-circuit comprises: a first switch transistor, a second switch transistor, a first resistor and a second resistor; wherein
a gate of the first switch transistor and a gate of the second switch transistor are connected to the input terminal of the control sub-circuit,
a source of the first switch transistor is connected to the first reference voltage terminal for inputting the first reference voltage signal, and a drain thereof is connected to a first terminal of the first resistor and the first control terminal of the output sub-circuit respectively;
a second terminal of the first resistor is connected to the third reference voltage terminal for inputting the third voltage signal and the first input terminal of the output sub-circuit respectively;
a source of the second switch transistor is connected to the second reference voltage terminal for inputting the second reference voltage signal, a drain thereof is connected to a first terminal of the second resistor and the second control terminal of the output sub-circuit respectively; and
a second terminal of the second resistor is connected to the fourth reference voltage terminal for inputting the fourth voltage signal and the second input terminal of the output sub-circuit respectively.

9. The voltage converting circuit according to claim 7, wherein the output sub-circuit comprises: a third switch transistor and a fourth switch transistor; wherein
a gate of the third switch transistor is connected to the drain of the second switch transistor, a source thereof is connected to the third reference voltage terminal for inputting the third voltage signal, and the gate and the source thereof are connected to the first terminal and the second terminal of the second resistor respectively, and a drain of the third switch transistor and a drain of the fourth switch transistor are connected to the signal output terminal; and
a gate of the fourth switch transistor is connected to the drain of the first switch transistor, a source thereof is connected to the fourth reference voltage terminal for inputting the fourth voltage signal, and the gate and the source thereof are connected to the first terminal and the second terminal of the first resistor respectively.

10. The voltage converting circuit according to claim 1, wherein a voltage value of the third voltage signal is greater than a voltage value of the first voltage signal;
a voltage value of the first voltage signal is greater than a voltage value of the second voltage signal; and
a voltage value of the second voltage signal is greater than a voltage value of the fourth voltage signal.

11. The voltage converting circuit according to claim 10, wherein a voltage value of the first reference voltage signal is smaller than or equal to a voltage value of the first voltage signal; and
a voltage value of the second reference signal is greater than or equal to a voltage value of the second voltage signal, and smaller than the voltage value of the first reference voltage signal.

12. The voltage converting circuit according to claim 11, wherein the first switch transistor and the third switch transistor are P type transistors; and
the second switch transistor and the fourth switch transistor are N type transistors.

13. A voltage converting method of the voltage converting circuit according to claim 1, comprising:
outputting a first conversion control signal to an output sub-circuit by the control sub-circuit and outputting a third voltage signal under control of the first conversion control signal by the output sub-circuit when a signal input terminal of the voltage conversion circuit is input a first voltage signal; and
outputting a second conversion control signal to the output sub-circuit by the control sub-circuit and outputting a fourth voltage signal under control of the second conversion control signal by the output sub-circuit when the signal input terminal of the voltage conversion circuit receives a second voltage signal.

14. The voltage converting method according to claim 13, wherein the control sub-circuit comprises: a first control sub-circuit and a second control sub-circuit,
outputting a first control signal to the second control sub-circuit by the first control sub-circuit and outputting the first conversion control signal to the output sub-circuit under control of the first control signal when the signal input terminal of the voltage converting circuit is input the first voltage signal; and
outputting a second control signal to the second control sub-circuit by the first control sub-circuit and outputting the second conversion control signal to the output sub-circuit under control of the second control signal when the signal input terminal of the voltage converting circuit is input the second voltage signal.

15. The voltage converting method according to claim 13, wherein
the first control sub-circuit comprises an inverter; an input terminal of the inverter is connected to the signal input terminal, and an output terminal thereof is connected to the control terminal of the second control sub-circuit;
the second control sub-circuit comprises: a first switch transistor, a second switch transistor, a first resistor and a second resistor wherein
a gate of the first switch transistor and a gate of the second switch transistor are connected to the output terminal of the inverter,
a source of the first switch transistor is connected to the first reference voltage terminal for inputting the first reference voltage signal, and a drain of the first switch transistor is connected to a first terminal of the first resistor and the first control terminal of the output sub-circuit respectively;
a second terminal of the first resistor is connected to the third reference voltage terminal for inputting the third voltage signal and the first input terminal of the output sub-circuit respectively;
a source of the second switch transistor is connected to the second reference voltage terminal for inputting the second reference voltage signal, and a drain thereof is connected to a first terminal of the second resistor and the second control terminal of the output sub-circuit respectively;
a second terminal of the second resistor is connected to the fourth reference voltage terminal for inputting the fourth voltage signal and the second input terminal of the output sub-circuit respectively;
the output sub-circuit comprises: a third switch transistor and a fourth switch transistor wherein
a gate of the third switch transistor is connected to the drain of the first switch transistor are connected, a source thereof is connected to the third reference voltage terminal for inputting the third voltage signal, and the gate and source thereof are connected to the first terminal and the second terminal of the first resistor respectively, and a drain thereof and a drain of the fourth switch transistor are connected to the signal output terminal; and
a gate of the fourth switch transistor is connected to the drain of the second switch transistor, a source thereof is connected to the fourth reference voltage terminal for inputting the fourth voltage signal, and the gate and source thereof are connected to the first terminal and the second terminal of the second resistor respectively.

16. The voltage converting method according to claim 13, wherein
the control sub-circuit comprises: a first switch transistor, a second switch transistor, a first resistor and a second resistor; wherein
a gate of the first switch transistor and a gate of the second switch transistor are connected to the input terminal of the control sub-circuit,
a source of the first switch transistor is connected to the first reference voltage for inputting the first reference voltage signal, and a drain thereof is connected to a first terminal of the first resistor and the first control terminal of the output sub-circuit respectively;
a second terminal of the first resistor is connected to the third reference voltage terminal for inputting the third voltage signal and the first input terminal of the output sub-circuit respectively;
a source of the second switch transistor is connected to the second reference voltage terminal for inputting the second reference voltage signal, a drain thereof is connected to a first terminal of the second resistor and the second control terminal of the output sub-circuit respectively;
a second terminal of the second resistor is connected to the fourth reference voltage terminal for inputting the fourth voltage signal and the second input terminal of the output sub-circuit respectively,
wherein the output sub-circuit comprises: a third switch transistor and a fourth switch transistor; wherein
a gate of the third switch transistor is connected to the drain of the second switch transistor, a source thereof is connected to the third reference voltage terminal for inputting the third voltage signal, and the gate and the source thereof are connected to the first terminal and the second terminal of the second resistor respectively, and a drain of the third switch transistor and a drain of the fourth switch transistor are connected to the signal output terminal; and
a gate of the fourth switch transistor is connected to the drain of the first switch transistor, a source thereof is connected to the fourth reference voltage terminal for inputting the fourth voltage signal, and the gate and the source thereof are connected to the first terminal and the second terminal of the first resistor respectively.

17. The voltage converting method according to claim 13, wherein
a voltage value of the third voltage signal is greater than a voltage value of the first voltage signal;
a voltage value of the first voltage signal is greater than a voltage value of the second voltage signal; and
a voltage value of the second voltage signal is greater than a voltage value of the fourth voltage signal.

18. A gate driving circuit, comprising: the voltage converting circuit according to claim 1.

19. A display panel, comprising: the gate driving circuit according to claim 18.

20. A display device, comprising: the display panel according to claim 19.
